(19) United States
(12) Patent Application Publication
(10) Pub. No.: US 2009/0238951 A1
(43) Pub. Date: Sep. 24, 2009

(54) VACUUM DEPOSITION APPARATUS AND CONTROL METHOD THEREOF

(75) Inventors: Young Woo LEE, Suwon (KR); Gee Lyong Kim, Suwon (KR); Jeong Min Cho, Yongin (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/244,875

(22) Filed: Oct. 3, 2008

(30) Foreign Application Priority Data
Mar. 24, 2008 (KR) 10-2008-0027059

(51) Int. Cl. C23C 16/52; C23C 16/04

(52) U.S. Cl. 427/11; 118/33; 118/708

(57) ABSTRACT

A vacuum deposition apparatus and a control method thereof can form very precise internal electrode patterns at a very high rate in a roll-to-roll manufacturing process, which is used for mass production of chip components such as a Multi-Layer Ceramic Capacitor (MLCC).

### CROSS-REFERENCE TO RELATED APPLICATIONS

This application claims the priority of Korean Patent Application No. 2008-0027059, filed on Mar. 24, 2008 in the Korean Intellectual Property Office, the disclosure of which is incorporated herein by reference.

### BACKGROUND OF THE INVENTION

1. Field of the Invention

The present invention relates to a vacuum deposition apparatus and a control method thereof, and more particularly, to a vacuum deposition apparatus, which can form precise internal electrode patterns in a roll-to-roll manufacturing process of chip components, and a control method thereof.

2. Description of the Related Art

In general, chip components such as a Multi-Layer Ceramic Capacitor (MLCC) and a chip inductor are manufactured by stacking a plurality of ceramic sheets, on which internal electrode patterns are formed, and then performing a series of processes on the stack of the ceramic sheets.

These chip components are required to have small size and high capacity due to latest trends of electronic products such as miniaturization, high integrity and multi-functionality.

The manufacture of the MLCC, which is representative of the chip components, is using a method that increases dielectric constant by modifying the composition or reduces the thickness of dielectric material while increasing the number of layers in order to meet the high capacity requirements.

A typical method of manufacturing the MLCC includes procedures of stacking a plurality of dielectric green sheets, on which internal electrode layers are printed, followed by compression, degreasing and high-temperature firing, forming terminals by printing external electrodes, and plating the terminal electrodes.

The thickness of the dielectric layers and the internal electrode layers is reduced to increase the number of layers per volume and thereby increase the capacity of the MLCC.

However, the thickness of the internal electrode layers can be reduced in a relatively smaller amount than the thickness of the dielectric layers because it is difficult to improve some factors of metal nano-particles of the internal electrode layers such as size, geometry and physical properties.

For this, an electrode forming method using a film manufacturing process such as sputtering, deposition or plating has been proposed. Furthermore, there is required a method of forming precise internal electrode patterns at high speed in a roll-to-roll thin film manufacturing apparatus, which is used for mass production.

### SUMMARY OF THE INVENTION

The present invention has been made to solve the foregoing problems with the prior art, and therefore the present invention is directed to a vacuum deposition apparatus, which can form very precise internal electrode patterns at a very high rate in a roll-to-roll manufacturing process, which is used for mass production of chip components such as a Multi-Layer Ceramic Capacitor (MLCC), and a control method thereof.

According to an aspect of the invention, the vacuum deposition apparatus includes a chamber having a thin film source; a mask-feeding unit provided inside the chamber to feed a mask having a pattern at a predetermined level of tension; a film-feeding unit for feeding a film web at a predetermined level of tension in such a manner that the thin film source forms an electrode pattern on the film web conforming to the pattern of the mask; and a tension-adjusting unit for adjusting the tension of the film web so as to be moved substantially simultaneously with the mask by friction against the mask in an area where the electrode pattern is formed on the film web.

The film-feeding unit may include an unwinding roller for unwinding the film web from a film roll; a winding roller for winding the film web provided from the unwinding roller; and a cooling drum for feeding the film web between the unwinding roller and the winding roller, so that the mask and the film web are in close contact with each other on a portion of the cooling drum so as to be moved by friction.

The mask-feeding unit may include a rolling unit for rolling the mask so as to be fed at the predetermined level of tension; and a drive unit for driving the rolling unit.

The rolling unit may include a drive roller for providing a drive force for feeding the mask; a guide roller for guiding the mask so as to be fed; and a tension roller rotating by friction against the mask, wherein the tension roller is displaceable at a predetermined interval to adjust the tension of the mask.

The drive roller may include a first drive roller rotating in contact with one side of the mask to generate a predetermined amount of frictional force so as to drive the mask to be fed; and a second drive roller rotating in a direction opposite to the first drive roller, in contact with the opposite side of the mask, to generate a predetermined amount of frictional force so as to drive the mask to be fed.

The drive unit may include a drive gear for generating the drive force; a drum gear rotating together with the cooling drum; a first drive roller gear rotating together with the first drive roller; a second drive roller gear rotating together with the second drive roller; and a connecting member connecting the drive gear, the drum gear, the first drive roller gear and the second drive roller gear to each other so as to rotate together by operation of the drive gear.

The tension-adjusting unit may include a sensor unit for detecting the tension of the film web; a clutch unit for controlling the film-feeding unit so as to adjust the tension of the film web; and a control unit for controlling the clutch unit based on a detection result from the sensor unit.

The tension-adjusting unit may include a first sensor part provided between the unwinding roller and the cooling drum to detect the tension of the film web; a second sensor part provided between the cooling drum and the winding roller to detect the tension of the film web; a first clutch for controlling the unwinding roller so as to adjust the tension of the film web; a second clutch for controlling the winding roller so as to adjust the tension of the film web; and a control unit for controlling at least one of the first and second clutches based on a detection result from at least one of the first and second sensor parts.

The first sensor part may include a first sensing roller provided between the unwinding roller and the cooling drum to detect a feeding rate of the film web while guiding the film web to be fed, and the second sensor part comprises a second sensing roller provided between the cooling drum and the winding roller to detect a feeding rate of the film web while guiding the film web to be fed.

The first clutch can be connected to the unwinding roller by a first belt or chain member, and the second clutch can be connected to the winding roller by a second belt or chain member.

The first clutch and the unwinding roller can be coupled integrally with each other, and the second clutch and the winding roller can be coupled integrally with each other.

The outside diameter ratio of the drum gear with the first drive roller gear or the second drive roller gear can be substantially equal with the outside diameter ratio of the cooling drum with the first drive roller or the second drive roller.

According to an aspect of the invention, the control method of a vacuum deposition apparatus includes steps of: driving a mask-feeding unit, which includes a drive roller and a tension roller, and a film-feeding unit, which includes an unwinding roller, a winding roll and a cooling drum, respectively; forming an electrode pattern on a film web, conforming to a pattern of a mask; and adjusting a tension of the film web so as to be moved substantially simultaneously with the mask by friction against the mask while the electrode pattern is being formed on the film web.

The driving step may include a step of driving the film-feeding unit in such a manner that the tension of the film web by side of the unwinding roller is greater than the tension of the film web by side of the winding roller.

The driving step may include a step of driving the drive roller of the mask-feeding unit and the cooling drum of the film-feeding unit so as to be synchronized with each other.

The tension adjusting step may include a step of setting a tension of the mask to be greater than a difference between the tension of the film web by side of the unwinding roller between and the tension of the film by side of the winding roller.

The tension adjusting step may include steps of: detecting, at a sensor unit, the tension of the film web fed by the film-feeding unit; comparing the tension of the film web, detected by the sensor unit, with a predetermined reference value; and controlling a clutch unit to compensate for a difference between the tension of the film web, detected by the sensor unit, and the reference value to adjust the tension of the film web.

The sensor unit may include a first sensing part for detecting the tension of the film by side of the unwinding roller and a second sensing part for detecting the tension of the film by side of the winding roller, wherein the detecting step may include a step of: detecting, at the first sensing part, the tension of the film by side of the unwinding roller, and at the second sensing part, the tension of the film by side of the winding roller.

The first sensing part may include a first sensing roller provided between the unwinding roller and the cooling drum to detect a feeding rate of the film web while guiding the film web to be fed, and the second sensor part comprises a second sensing roller provided between the cooling drum and the winding roller to detect a feeding rate of the film web while guiding the film web to be fed.

The clutch unit may include a first clutch for controlling a rotation speed of the unwinding roller and a second clutch for controlling a rotation speed of the winding roller, wherein the controlling step may include a step of: controlling, at the first clutch and the second clutch, the rotation speed of the unwinding roller and the rotation speed of the winding roller, respectively, based on a detection result from the sensor unit.

As set forth above, the vacuum deposition apparatus and the control method thereof according to the invention can form very precise internal electrodes of chip components in a roll-to-roll chip manufacturing process by forming the internal electrode patterns at a high speed and feeding the film web to be substantially synchronized with the mask through correct tension adjustment.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic configuration view illustrating a vacuum deposition apparatus according to an embodiment of the present invention;

FIG. 2 is a schematic configuration view illustrating a drive unit of the vacuum deposition apparatus shown in FIG. 1; and

FIG. 3 is a block diagram illustrating a control system of the vacuum deposition apparatus shown in FIG. 2.

### DETAILED DESCRIPTION OF THE PREFERRED EMBODIMENT

Hereinafter, a vacuum deposition apparatus and a control method thereof according to the present invention will be described more fully with reference to the accompanying drawings, in which exemplary embodiments thereof are shown.

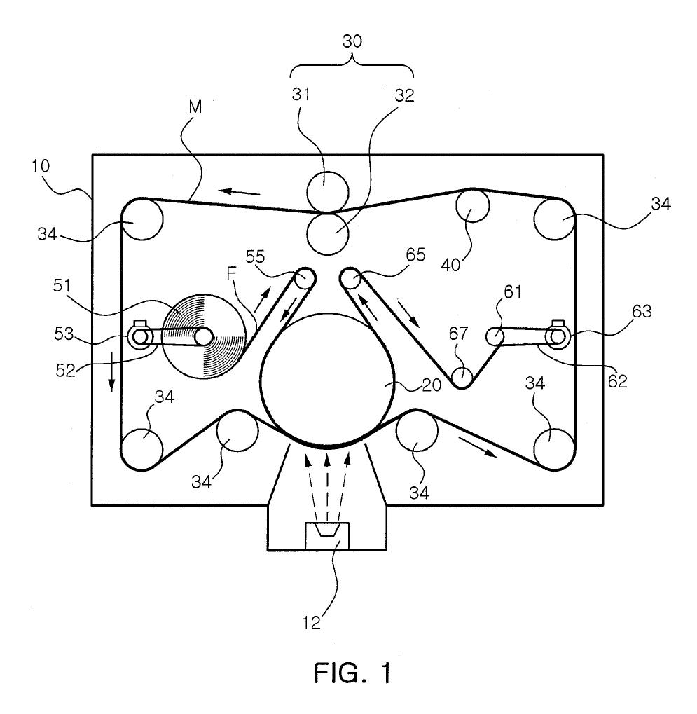

Firstly, a vacuum deposition apparatus according to an embodiment of the present invention will be described in detail with reference to FIG. 1, which schematically illustrates the vacuum deposition apparatus of the present invention.

As shown in FIG. 1, the vacuum deposition apparatus according to an embodiment of the present invention includes a chamber 10, a mask-feeding unit, a film-feeding unit and a tension-adjusting unit.

A thin film source unit 12 provided in the chamber 10 acts to apply a source of metal thin film (hereinafter, referred to as “thin film source”) including metal particles on a closely stacked structure of a film web F and a mask M, which is traveling inside the chamber 10, so that the thin film source forms a predetermined pattern.

The thin film source unit 12 is a device that supplies the thin film source, and includes a heating system or a sputtering cathode device for depositing the thin film on the film web.

Since the mask M is formed with a pattern conforming to any intended electrode geometry, the metal particles supplied from the thin film source unit 12 are deposited on the film web F according to the pattern of the mask M, thereby forming the electrode pattern. This process will be described in more detail later in the specification.

As shown in FIG. 1, the mask-feeding unit enables the mask M to rotate along an endless track at a substantially constant level of tension.

The mask-feeding unit includes a rolling unit and a drive unit for driving the rolling unit. As illustrated in FIG. 1, an embodiment of the rolling unit includes drive rollers 30, guide rollers 34 and a tension roller 40.

The rolling unit is a device that feeds the mask M under a constant level of tension, and the drive rollers 30 are a device that provides a driving force for feeding the mask M.

The drive rollers 30 are rotated by the drive unit so as to drive the mask M using the friction between the drive rollers 30 and the mask M. As shown in FIG. 1, the drive rollers 30 can include a first drive roller 31 and a second drive roller 32.

As shown in FIG. 1, the first drive roller 31 and the second drive roller 32 are in close contact with both sides of the mask M so as to maintain the friction against the mask M when they are rotating.

The first and second drive rollers 31 and 32 rotate in opposite directions to feed the mask M in one direction owing to their respective friction against the mask M.

The guide rollers 34 are a device that guides the mask M to be fed, and as shown in FIG. 1, can be provided in several places if necessary. The guide rollers 34 are rotated by friction against the mask M, preferably, without a driving force.

The tension roller 40 is a device that adjusts the tension of the mask M. The tension roller 40 is constructed to be moved up and down to a predetermined interval and be rotated by friction against the mask M.

Specifically, the tension roller 40 can be fixed in an elevated position in order to set the moving mask M to be tighter, thereby increasing the tension, or in a lowered position in order to set the moving mask to be looser, thereby reducing the tension.

The operation of the tension roller 40 can be automatically performed by a control unit (not shown) or manually controlled by a user.

The tension applied to the mask M may preferably be in the range from 0 to 10 kgf.

It is more preferable to increase the frictional force between the mask M and the drive rollers 30 or between the mask M and the guide rollers 34. In order to increase the frictional force, the drive rollers 30, the tension roller 40 or the guide rollers 34 can preferably be coated with or made of high friction material.

Below, a description will be given of the film-feeding unit of the vacuum deposition apparatus according to an embodiment of the present invention with reference to FIG. 1.

As shown in FIG. 1, the film-feeding unit of the vacuum deposition apparatus of this embodiment includes an unwinding roller 51, a winding roller 61 and a cooling drum 20.

The unwinding roller 51 acts to unwind the film web F from a film roll, and the winding roller 61 acts to wind again the film web F, which was unrolled by the unwinding roller 51.

A guide roller 67 is provided by the side of the winding roller 61, particularly, upstream of the winding roller 61 so as to guide the feeding of the film web F. Alternatively, the guide roller can be provided adjacent to the unwinding roller 61 to guide the feeding of the film web F.

The film web F unwound from the unwinding roller 51 is fed to the winding roller 61, guided by the cooling drum 20. The cooling drum 20 is rotated by friction against the film web F so as to bring the mask M into close contact with the film web F on one side (e.g., an outer circumferential portion) thereof.

The thin film source including metal particles, supplied from the thin film source unit 12, is deposited on overlapping portions of the mask M and a portion of the film web F, which are in close contact with each other on the cooling drum 20. Here, the cooling drum 20 also functions to cool the film web F, which is heated during the deposition.

When the film web F and the mask M are moving in close contact with each other on the cooling drum 20, the moving speed of the film web F should be substantially the same as that of the mask M.

Moving the film web F and the mask M at different speeds is not preferable since a thin film pattern different from that of the mask M can be formed on the film web F due to the different moving speeds during the deposition

The tension-adjusting unit of the present invention is a device that adjusts the tension of the film web F so that the mask M and the film web F can keep substantially the same moving speed as described above.

The vacuum deposition apparatus of the present invention is so constructed that the tension of the mask M is substantially maintained uniform and the tension of the film web F is adjusted by the tension-adjusting unit, so that the film web F and the mask M can be fed in the same speed in close contact with the cooling drum 20 in an area where deposition is performed.

The tension-adjusting unit according to an embodiment of the present invention includes a sensor unit, a clutch unit and a control unit.

The sensor unit includes a first senor part, which is disposed between the unwinding roller and the cooling drum to detect the tension of the film web, and a second sensor part, which is disposed between the cooling drum and the winding roller to detect the tension of the film web.

FIG. 1 illustrates a first sensing roller 55 as an example of the first sensor part and a second sensing roller 65 as an example of the second sensor part.

The first sensing roller 55 is provided between the unwinding roller 51 and the cooling drum 20 so as to guide the feeding of the film web F and detect the tension of the film web F.

The second sensing roller 65 is provided between the winding roller 61 and the cooling drum 20 so as to guide the feeding of the film web F and detect the tension of the film web F.

The tension of the film web F can preferably be in the range from 0 to 5 kgf.

FIG. 1 also illustrates, as an example of the clutch unit, a first clutch 53 for controlling the unwinding roller 51 and a second clutch 63 for controlling the winding roller 61.

As shown in FIG. 1, the first clutch 53 and the unwinding roller 51 are connected to each other by a first belt/chain member 52, and the second clutch 63 and the winding roller 61 are connected to each other by a second belt/chain member 62.

The tension-adjusting unit is not limited to the case where the belt/chain members are used to connect the first clutch 53 to the unwinding roller 51 and the second clutch 63 to the winding roller 61, but is also applicable to a case where the clutch is directly coupled to the roller to control the latter.

That is, the first clutch 53 and the second clutch 63 can be directly coupled to the unwinding roller 51 and the winding roller 61, respectively, to control the rotational speed of the latter.

Although not shown in FIG. 1, the tension-adjusting unit of the present invention can preferably include a control unit, which is connected to the sensor unit and the clutch unit, respectively, to control the latter.

Specifically, the first sensing roller 55 detects the tension of the film web F by the side of the unwinding roller 51 and the second sensing roller 65 detects the tension of the film web F by the side of the winding roller 61. Then, the control unit compares the detected values with a predetermined reference value, and if there is a difference from the reference value, operates the first clutch 53 and/or the second clutch 63 to control the unwinding roller 51 and/or the winding roller 61.

Details of the control method of the vacuum deposition apparatus of the present invention like this will be described later.

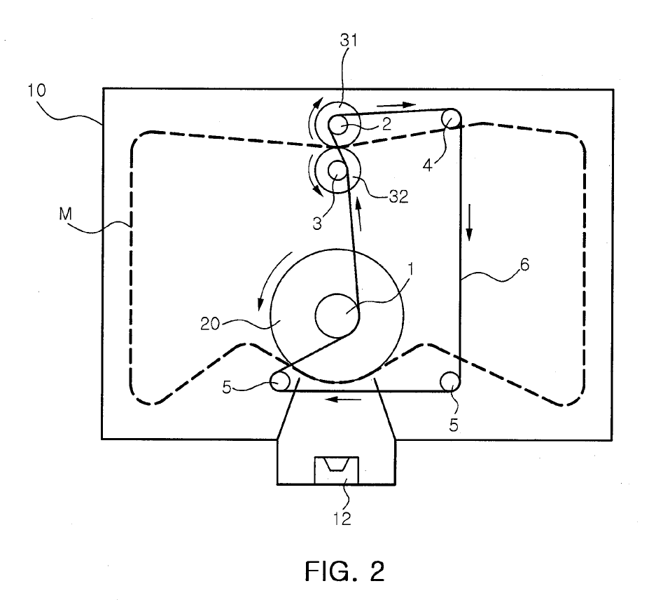

Referring to FIG. 2, the following description will be given of the drive unit of the vacuum deposition apparatus according to an embodiment of the present invention shown in FIG. 1. FIG. 2 is a schematic configuration view illustrating the drive unit of the vacuum deposition apparatus shown in FIG. 1.

As shown in FIG. 2, the drive unit of the vacuum deposition apparatus of the present invention drives the drive rollers 31 and 32 and the cooling drum 20 of the mask-feeding unit to be substantially synchronous with each other.

Specifically, a first drive roller gear 2 rotating together with the first drive roller 31, a second drive roller gear 3 rotating together with the second drive roller gear 32 and a drum gear 1 rotating together with the cooling drum 20 are connected to each other by a connecting member 6 and thus are driven simultaneously.

A drive gear 4 is additionally provided to transmit a driving force to the connecting member 6. However, this is not intended to be limiting, but the drum gear 1, the first drive roller gear 2 or the second drive roller gear 3 can also be constructed to transmit the driving force.

As shown in FIG. 2, a guide gear 5 can also be arranged suitable to some usages of synchronous operation in order to guide the movement of the connecting member 6.

The connecting member 6 can preferably be constructed with, for example, a timing belt in order to prevent slips. However, this is not intended to be limiting, but the connecting member 6 can be constructed with various types of belts or chains.

Consequently, when a driving force is supplied from the drive gear 4, the connecting member 6 is driven to rotate the drum gear 1, the first drive roller gear 2 and the second drive roller gear 3 at a substantially constant rate, which in turn rotate the cooling drum 20, the first drive roller 31 and the second drive roller 32 at a substantially constant rate, thereby feeding the mask M at a substantially constant tension.

Preferably, the first and second drive roller gears 2 and 3 can have substantially the same diameter, and the first and second drive rollers 31 and 32 can have substantially the same diameter.

The ratio of the outside diameter of the drum gear 1 with the first drive roller gear 2 (or with the second drive roller gear 3) can preferably be set substantially the same as the ratio of the outside diameter of the cooling drum 20 with the first drive roller 31 (or with the second drive roller 32).

Since the outside diameter ratios are set the same, the speed of the mask M fed by the first and second drive rollers 31 and 32 is substantially the same as the speed of the mask M, which is being moved on and in close contact with the cooling drum 20.

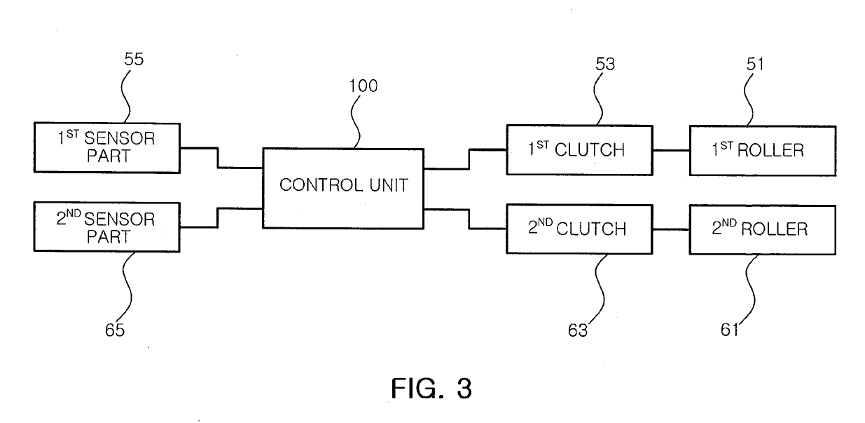

Below, a description will be given of the control method of the vacuum deposition apparatus according to an embodiment of the present invention with reference to FIGS. 1 and 3, in which FIG. 3 is a block diagram illustrating a control system of the vacuum deposition apparatus shown in FIG. 2.

As shown in FIGS. 1 and 3, the control system of the vacuum deposition apparatus according to an embodiment of the present invention includes the first sensor part (e.g., the first sensing roller 55), the second sensor part (e.g., the second sensing roller 65), the first clutch 53 and the second clutch 63, which are connected to the control unit 100.

The sensor parts, the clutches and the control unit are constructed to control the film-feeding unit so that the film web F and the mask M can be moved at substantially the same speed in a deposition step where electrodes are formed on the film web F.

Here, the mask fed by the mask-feeding unit is generally fixed at a constant level of tension.

Accordingly, the control method of the vacuum deposition apparatus of the present invention includes a driving step, an electrode forming step and a tension adjusting step.

The driving step involves operating the mask-feeding unit and the film-feeding unit so that the mask M and the film web F are fed respectively.

The electrode forming step involves providing a thin film source from the thin film source unit 12 to the mask M and the film web F stacked one atop the other when they are moving on the cooling drum 20, so that metal particles in the thin film source are deposited onto the film web M to thereby form an electrode pattern matching the pattern of the mask M.

The tension adjusting step involves adjusting the tension of the film web F so that the mask M and the film F move at substantially the same speed and thus the electrode pattern matching the pattern of the mask M is precisely formed on the film web F.

In the meantime, the driving step can preferably operate the film-feeding unit in such a manner that the tension of the film web by the side of the unwinding roller can be set to be greater than that of the film web by the side of the winding roller.

This is to prevent the film web from slipping on the cooling drum and facilitate adjusting the tension of the film web since the film web will slip on the cooling drum, thereby making it more difficult to adjust the tension, when the tension of the film web by the side of winding roller is greater.

Further, the mask-feeding unit can preferably be operated in such a manner that the drive roller and the cooling drum are synchronized with each other. Since this feature was described before, details thereof will not be described further.

The difference in the tension of the film web between the unwinding roller's side and the winding roller's side is compensated by the frictional force between the mask and the film web. That is, the frictional force cancels a force corresponding to a difference in the tension of the film web between the unwinding roller's side and the winding roller's side, so that the mask can move together with the film web by dragging the film web by the frictional force.

When the frictional force between the mask and the film web is set to be substantially greater than the difference in the tension of the film web between the unwinding roller's side and the winding roller's side, a small amount of misalignment can be corrected by the force of the mask and the cooling drum holding the film web even if the control of the first clutch 53 and the second clutch 63 is slightly misaligned.

Here, the difference in the tension of the film web between the unwinding roller's side and the winding roller's side can be correctly controlled as follows: The first sensing roller 55 detects the tension of the film web by the side of the unwinding roller and the second sensing roller 65 detects the tension of the film web by the side of the winding roller; The control unit compares the detected tensions with a reference value, and if there is a difference, controls the first and second clutches 53 and 63 to adjust the speed of the unwinding roller 51 and the speed of the winding roller 61, respectively, by feeding back the difference.

As set forth above, the tension of the film by the unwinding roller's side and the tension of the film by the winding roller's side can be correctly controlled, so that simultaneous feeding can be substantially correctly enabled by the frictional force between the mask and the film web. This as a result enables to form precise internal electrode patterns, which can be mass produced by a roll-to-roll method.

While the present invention has been shown and described in connection with the exemplary embodiments, it will be apparent to those skilled in the art that modifications and variations can be made without departing from the spirit and scope of the present invention as defined by the appended claims.

What is claimed is:

1. A vacuum deposition apparatus comprising:
a chamber having a thin film source;
a mask-feeding unit provided inside the chamber to feed a mask having a pattern at a predetermined level of tension;
a film-feeding unit for feeding a film web at a predetermined level of tension in such a manner that the thin film source forms an electrode pattern on the film web conforming to the pattern of the mask; and
a tension-adjusting unit for adjusting the tension of the film web so as to be moved substantially simultaneously with the mask by friction against the mask in an area where the electrode pattern is formed on the film web.

2. The vacuum deposition apparatus of claim 1, wherein the film-feeding unit includes:
an unwinding roller for unwinding the film web from a film roll;
a winding roller for winding the film web provided from the unwinding roller; and
a cooling drum for feeding the film web between the unwinding roller and the winding roller, so that the mask and the film web are in close contact with each other on a portion of the cooling drum so as to be moved by friction.

3. The vacuum deposition apparatus of claim 2, wherein the mask-feeding unit includes:
a rolling unit for rolling the mask so as to be fed at the predetermined level of tension; and
a drive unit for driving the rolling unit.

4. The vacuum deposition apparatus of claim 3, wherein the rolling unit includes:
a drive roller for providing a drive force for feeding the mask;
a guide roller for guiding the mask so as to be fed; and
a tension roller rotating by friction against the mask, wherein the tension roller is displaceable at a predetermined interval to adjust the tension of the mask.

5. The vacuum deposition apparatus of claim 4, wherein the drive roller includes:
a first drive roller rotating in contact with one side of the mask to generate a predetermined amount of frictional force so as to drive the mask to be fed; and
a second drive roller rotating in a direction opposite to the first drive roller, in contact with the opposite side of the mask, to generate a predetermined amount of frictional force so as to drive the mask to be fed.

6. The vacuum deposition apparatus of claim 5, wherein the drive unit includes:
a drive gear for generating the drive force;
a drum gear rotating together with the cooling drum;
a first drive roller gear rotating together with the first drive roller;
a second drive roller gear rotating together with the second drive roller; and
a connecting member connecting the drive gear, the drum gear, the first drive roller gear and the second drive roller gear to each other so as to rotate together by operation of the drive gear.

7. The vacuum deposition apparatus of claim 1, wherein the tension-adjusting unit includes:
a sensor unit for detecting the tension of the film web;
a clutch unit for controlling the film-feeding unit so as to adjust the tension of the film web; and
a control unit for controlling the clutch unit based on a detection result from the sensor unit.

8. The vacuum deposition apparatus of claim 2, wherein the tension-adjusting unit includes:
a first sensor part provided between the unwinding roller and the cooling drum to detect the tension of the film web;
a second sensor part provided between the cooling drum and the winding roller to detect the tension of the film web;
a first clutch for controlling the unwinding roller so as to adjust the tension of the film web;
a second clutch for controlling the winding roller so as to adjust the tension of the film web; and
a control unit for controlling at least one of the first and second clutches based on a detection result from at least one of the first and second sensor parts.

9. The vacuum deposition apparatus of claim 8, wherein the first sensor part comprises a first sensing roller provided between the unwinding roller and the cooling drum to detect a feeding rate of the film web while guiding the film web to be fed, and the second sensor part comprises a second sensing roller provided between the cooling drum and the winding roller to detect a feeding rate of the film web while guiding the film web to be fed.

10. The vacuum deposition apparatus of claim 8, wherein the first clutch is connected to the unwinding roller by a first belt or chain member, and the second clutch is connected to the winding roller by a second belt or chain member.

11. The vacuum deposition apparatus of claim 8, wherein the first clutch and the unwinding roller are coupled integrally with each other, and the second clutch and the winding roller are coupled integrally with each other.

12. The vacuum deposition apparatus of claim 6, wherein an outside diameter ratio of the drum gear with the first drive roller gear or the second drive roller gear is substantially equal with an outside diameter ratio of the cooling drum with the first drive roller or the second drive roller.

13. A control method of a vacuum deposition apparatus comprising:
driving a mask-feeding unit, which includes a drive roller and a tension roller, and a film-feeding unit, which includes an unwinding roller, a winding roll and a cooling drum, respectively;
forming an electrode pattern on a film web, conforming to a pattern of a mask; and
adjusting a tension of the film web so as to be moved substantially simultaneously with the mask by friction against the mask while the electrode pattern is being formed on the film web.

14. The control method of claim 13, wherein the driving step comprises driving the film-feeding unit in such a manner that the tension of the film web by side of the unwinding roller is greater than the tension of the film web by side of the winding roller.

15. The control method of claim 13, wherein the driving step comprises driving the drive roller of the mask-feeding unit and the cooling drum of the film-feeding unit so as to be synchronized with each other.

16. The control method of claim 15, wherein the tension adjusting step comprises setting a tension of the mask to be greater than a difference between the tension of the film web by side of the unwinding roller between and the tension of the film by side of the winding roller.

17. The control method of claim 13, wherein the tension adjusting step comprises:
detecting, at a sensor unit, the tension of the film web fed by the film-feeding unit;
comparing the tension of the film web, detected by the sensor unit, with a predetermined reference value; and
controlling a clutch unit to compensate for a difference between the tension of the film web, detected by the sensor unit, and the reference value to adjust the tension of the film web.

18. The control method of claim 17, wherein the sensor unit includes a first sensing part for detecting the tension of the film by side of the unwinding roller and a second sensing part for detecting the tension of the film by side of the winding roller, and
wherein the detecting step comprises detecting, at the first sensing part, the tension of the film by side of the unwinding roller, and at the second sensing part, the tension of the film by side of the winding roller.

19. The control method of claim 18, wherein the first sensing part comprises a first sensing roller provided between the unwinding roller and the cooling drum to detect a feeding rate of the film web while guiding the film web to be fed, and the second sensor part comprises a second sensing roller provided between the cooling drum and the winding roller to detect a feeding rate of the film web while guiding the film web to be fed.

20. The control method of claim 17, wherein the clutch unit includes a first clutch for controlling a rotation speed of the unwinding roller and a second clutch for controlling a rotation speed of the winding roller, and
wherein the controlling step comprises: controlling, at the first clutch and the second clutch, the rotation speed of the unwinding roller and the rotation speed of the winding roller, respectively, based on a detection result from the sensor unit.

21. The control method of claim 13, further comprising adjusting, at the tension roller, a tension of the mask if the tension of the mask is beyond a predetermined range.
